(19) United States
(12) Patent Application Publication
(10) Pub. No.: US 2024/0218246 A1
(43) Pub. Date: Jul. 4, 2024

(54) LIGHT-EMITTING DEVICE, ILLUMINATION DEVICE, AND NIGHT-VISION DEVICE

(71) Applicant: NICHIA CORPORATION, Anan-shi (JP)

(72) Inventor: Yoshinori MURAZAKI, Komatsushima-shi (JP)

(73) Assignee: NICHIA CORPORATION, Anan-shi (JP)

(21) Appl. No.: 18/539,105

(22) Filed: Dec. 13, 2023

(30) Foreign Application Priority Data
Dec. 15, 2022 (JP) 2022-200341

(51) Int. Cl. C09K 11/77; C09K 11/02; C09K 11/68; H01L 33/50

(52) U.S. Cl. CPC C09K 11/7774; C09K 11/02; C09K 11/684; C09K 11/685; C09K 11/7708; C09K 11/77342; C09K 11/77347; C09K 11/77348; C09K 11/7738; H01L 33/502

(57) ABSTRACT

A light-emitting device includes a light-emitting element and a phosphor that absorbs at least a portion of light from the light-emitting element and emits light. The phosphor includes two or more types of phosphors each having a light emission peak wavelength in a different range. The two or more types of phosphors are selected from the group consisting of a first phosphor having a light emission peak wavelength within a first range of 700 nm to less than 800 nm, a second phosphor having a light emission peak wavelength within a second range of 800 nm to less than 1100 nm, and a third phosphor having a light emission peak wavelength within a third range of 1100 nm to less than 1500 nm.

### CROSS-REFERENCE TO RELATED APPLICATIONS

The present application claims priority under 35 U.S.C. § 119 to Japanese Patent Application No. 2022-200341, filed Dec. 15, 2022, the content of which is hereby incorporated by reference in its entirety.

### BACKGROUND

### 1. Technical Field

The present disclosure relates to a light-emitting device, an illumination device, and a night-vision device.

### 2. Description of Related Art

For the purpose of security or the like, an imaging system including a camera is sometimes installed in a building. In addition, in order to assist driving of an autonomous driving vehicle, an imaging system that transmits image data from a camera mounted on the autonomous driving vehicle to an operator is sometimes used. Some of these imaging systems are provided with means for emitting near-infrared light, such that a visual image of an object to be irradiated (such as a human or an animal) can be obtained even in a dark place.

For example, Japanese Patent Publication No. 2006-109118 discloses a monitoring device including a plurality of cameras having a near-infrared imaging function for night vision and a near-infrared illumination unit using a near-infrared LED.

### SUMMARY

An object of the present disclosure is to provide a light-emitting device that can irradiate an object to be irradiated with light within a wavelength range of near-infrared light, and an illumination device and a night-vision device each using the light-emitting device.

A first aspect is a light-emitting device including a light-emitting element and a phosphor that absorbs at least a portion of light from the light-emitting element and emits light. The phosphor includes two or more types of phosphors each having a light emission peak wavelength in a different range. The two or more types of phosphors are selected from the group consisting of a first phosphor having a light emission peak wavelength within a first range of 700 nm to less than 800 nm, a second phosphor having a light emission peak wavelength within a second range of 800 nm to less than 1100 nm, and a third phosphor having a light emission peak wavelength within a third range of 1100 nm to less than 1500 nm.

A second aspect is an illumination device including the light-emitting device and at least one auxiliary light source selected from the group consisting of a tungsten lamp, a xenon lamp, and a halogen lamp.

A third aspect is a night-vision device including the light-emitting device or the illumination device, an infrared camera, and an image processing unit that analyzes an image captured by the infrared camera and reproduces a color in a visible light region.

With the present disclosure, there can be provided a light-emitting device that can irradiate an object to be irradiated with light within a wavelength range of near-infrared light, and an illumination device and a night-vision device each using the light-emitting device.

### BRIEF DESCRIPTION OF THE DRAWINGS

A more complete appreciation of embodiments of the invention and many of the attendant advantages thereof will be readily obtained by reference to the following detailed description when considered in connection with the accompanying drawings.

FIG. 1 is a schematic cross-sectional view of an example of a light-emitting device.

FIG. 2 is a schematic cross-sectional view of an example of a light-emitting device.

FIG. 3 is a schematic cross-sectional view of an example of a light-emitting device.

FIG. 4 is a schematic cross-sectional view of an example of a light-emitting device.

FIG. 5 is a schematic cross-sectional view of an example of a light-emitting device.

FIG. 6 is a schematic cross-sectional view of an example of a light-emitting device.

FIG. 7 is a schematic configuration diagram of an example of a night-vision device.

FIG. 8 is a schematic configuration diagram of an example of a night-vision device.

FIG. 9 is a graph showing emission spectra of light-emitting devices according to Examples 1 and 2.

FIG. 10 is a graph showing an emission spectrum of a light-emitting device according to Example 3.

### DETAILED DESCRIPTION

### Description of Embodiments

Hereinafter, a light-emitting device, an illumination device, and a night-vision device according to the present disclosure will be described. However, the embodiments to be described below are examples for embodying a technical concept of the present invention, and the present invention is not limited to the following light-emitting device, illumination device, and night-vision device. Also, the members in the claims are not in any way limited to the members in the embodiments. In particular, dimensions, materials, shapes, relative arrangements, and the like of the components described in the embodiments are not intended to limit the scope of the present disclosure thereto, unless otherwise specified, and are merely exemplary. Note that members illustrated in the drawings may be exaggerated in size and positional relationship and may be simplified in shape. In the following description, the same names and reference signs denote members that are the same or of the same quality in principle. Note that, regarding light, the relationship between the color name and the chromaticity coordinates, the relationship between the wavelength range of light and the color name of monochromatic light, and the like conform to JIS Z 8110. In the present specification, a full width at half maximum refers to a wavelength width at which an emission intensity is 50% of an emission intensity at a light emission peak wavelength showing a maximum emission intensity in an emission spectrum. A wavelength range from near-infrared light to infrared light refers to a wavelength range within a range from 780 nm to 3000 nm. A wavelength range of visible light refers to a wavelength range from 380 nm to less than 780 nm.

The light-emitting device includes a light-emitting element and a phosphor that absorbs at a least a portion of light from the light-emitting element and emits light. The phosphor includes at least two types of phosphors each having a light emission peak wavelength in a different range. The at least two types of phosphors are selected from the group consisting of a first phosphor having a light emission peak wavelength within a first range from 700 nm to less than 800 nm, a second phosphor having a light emission peak wavelength within a second range from 800 nm to less than 1100 nm, and a third phosphor having a light emission peak wavelength within a third range from 1100 nm to less than 1500 nm. The light-emitting device can emit light within a wavelength range of near-infrared light with use of light from the light-emitting element and light from the phosphor that absorbs at least a portion of the light from the light-emitting element and emits light. The first phosphor having a light emission peak wavelength in a first range from 700 nm to less than 800 nm absorbs at least a portion of the light from the light-emitting element, and emits light having an emission intensity within a range from 780 nm to 3000 nm, which is a wavelength range from near-infrared light to infrared light. An object to be irradiated that is irradiated with light in a wavelength range of near-infrared light from the light-emitting device reflects light in the wavelength range of near-infrared light. As will be described below, by analyzing differences in intensity between wavelengths of the reflected near-infrared light, differences in reflectance between wavelengths of the reflected near-infrared light, or the like, a colored image obtained from image data of the object to be irradiated can be displayed. In the present specification, the wavelength ranges in which the light emission peak wavelengths of the phosphors are present are referred to as a first range, a second range, a third range, and a fourth range in correspondence with the first phosphor, the second phosphor, the third phosphor, and a fourth phosphor to be described below, respectively.

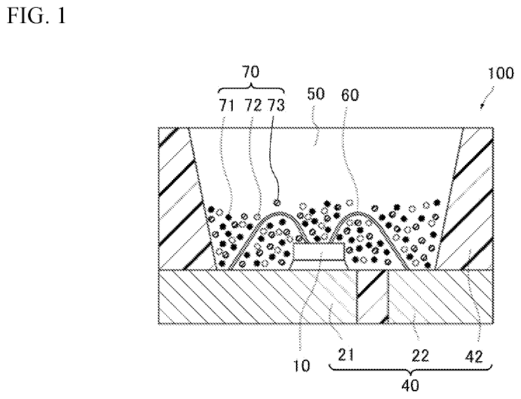

FIG. 1 is a schematic cross-sectional view illustrating a first example of a light-emitting device. A light-emitting device 100 includes a light-emitting element 10, and a phosphor 70 that absorbs at least a portion of light from the light-emitting element 10 and emits light. The light-emitting device 100 includes a molded body 40 and a wavelength conversion member 50 including the phosphor 70. The molded body 40 is formed by integrally molding a first lead 21, a second lead 22, and a resin portion 42 including a thermoplastic resin or a thermosetting resin. The molded body 40 has a recessed portion including a bottom surface and lateral surfaces, and the light-emitting element 10 is disposed on the bottom surface of the recessed portion. The light-emitting element 10 includes a pair of positive and negative electrodes, and the pair of positive and negative electrodes are electrically connected to the first lead 21 and the second lead 22, respectively, via wires 60. The light-emitting element 10 is covered with the wavelength conversion member 50. The wavelength conversion member 50 preferably includes the phosphor 70 that absorbs at least a portion of the light from the light-emitting element 10 and emits light, and a light-transmissive material that also serves as a sealing material to cover and protect the light-emitting element 10. The phosphor 70 includes at least two types of phosphors each having a light emission peak wavelength in a different range. The at least two types of phosphors are selected from the group consisting of a first phosphor 71 that emits light having a light emission peak wavelength within a first range from 700 nm to less than 800 nm, a second phosphor 72 that emits light having a light emission peak wavelength within a second range from 800 nm to less than 1100 nm, and a third phosphor 73 that emits light having a light emission peak wavelength within a third range from 1100 nm to less than 1500 nm. The light-emitting device 100 emits light when power is supplied to the light-emitting element 10 from the outside via the first lead 21 and the second lead 22.

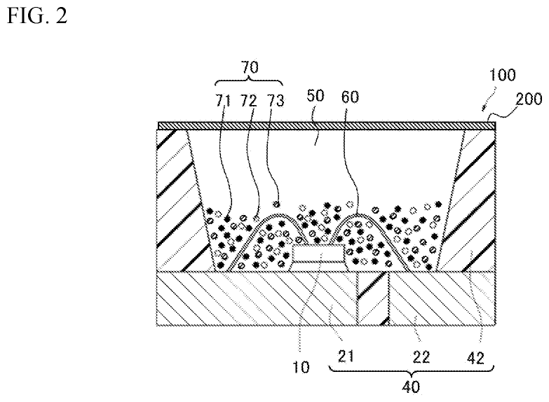

FIG. 2 is a schematic cross-sectional view illustrating a second example of a light-emitting device. The light-emitting device 100 may include a cut filter 200 having an average transmittance of 5% or less for light in a wavelength range from 400 nm to 780 nm on a light emission side of the wavelength conversion member 50. It is preferable that the cut filter 200 is movably disposed such that it can be disposed so as to block the light emission side of the wavelength conversion member 50 or can be disposed so as not to block the light emission side.

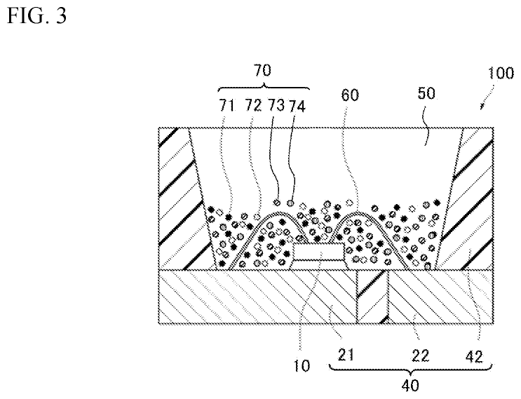

FIG. 3 is a schematic cross-sectional view illustrating a third example of a light-emitting device. In the light-emitting device 100, the phosphor 70 included in the wavelength conversion member 50 may include a fourth phosphor 74 that wavelength-converts light from the light-emitting element 10 and has a light emission peak wavelength within the fourth range from 400 nm to less than 700 nm. When the light-emitting device 100 includes the fourth phosphor 74, light in a wavelength range of near-infrared light and light in a wavelength range of visible light can be emitted from the light-emitting device 100, and visibility of an object to be irradiated can be improved in the case in which the surroundings are dark or the case in which confidentiality, such as acquisition of image data without being noticed by the object to be irradiated, is unnecessary.

The wavelength conversion member preferably includes a light-transmissive material that also serves as a sealing material. A resin selected from a thermoplastic resin and a thermosetting resin can be used for the light-transmissive material that also serves as a sealing material. In consideration of manufacturability, examples of the resin that is used as the light-transmissive material include a silicone resin and an epoxy resin. The wavelength conversion member may include another component such as a filler, a light stabilizer, or a colorant in addition to the phosphor and the light-transmissive material. Examples of the filler can include silicon oxide, barium titanate, titanium oxide, and aluminum oxide. The amount of the component other than the phosphor and the light-transmissive material in the wavelength conversion member can be set in a suitable range, in accordance with a size of the intended light-emitting device and a color tone. For example, the amount of the component other than the phosphor and the light-transmissive material in the wavelength conversion member can be set in a range from 0.01 parts by mass to 20 parts by mass with respect to 100 parts by mass of the light-transmissive material.

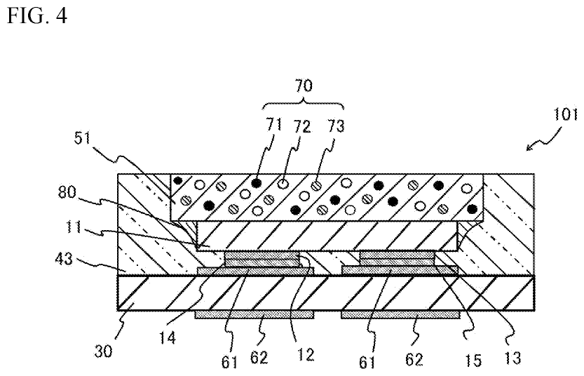

FIG. 4 is a schematic cross-sectional view illustrating a fourth example of a light-emitting device. A light-emitting device 101 includes a light-emitting element 11, and a wavelength conversion member 51 including the phosphor 70 that absorbs at least a portion of light from the light-emitting element 11 and emits light. The phosphor 70 includes at least two types of phosphors each having a light emission peak wavelength in a different range. The at least two types of phosphors are selected from the group consisting of a first phosphor 71 that emits light having a light emission peak wavelength within a first range from 700 nm to less than 800 nm, a second phosphor 72 that emits light having a light emission peak wavelength within a second range from 800 nm to less than 1100 nm, and a third phosphor 73 that emits light having a light emission peak wavelength within a third range from 1100 nm to less than 1500 nm. The light-emitting device 101 includes conductive members 61, 61, such as a wiring pattern where the light-emitting element 11 is mounted, on at least one surface of a support 30. The support 30 is provided with conductive members 62, 62 on a surface different from the surface on which the light-emitting element 11 is mounted. In the light-emitting element 11, electrodes 12, 13 formed on the light-emitting element 11 are connected to the conductive members 61, 61 of the support 30 via connecting members 14, 15, such as a bump. The light-emitting device 101 includes the wavelength conversion member 51 that is in contact with the light-emitting element 11 and includes the phosphor 70. The wavelength conversion member 51 also includes a light-transmissive material. A light reflecting member 43 is provided around the light-emitting element 11 and the wavelength conversion member 51. The light-emitting device 101 includes a light guide member 80 such that light from the lateral surfaces of the light-emitting element 11 is incident on the wavelength conversion member 51.

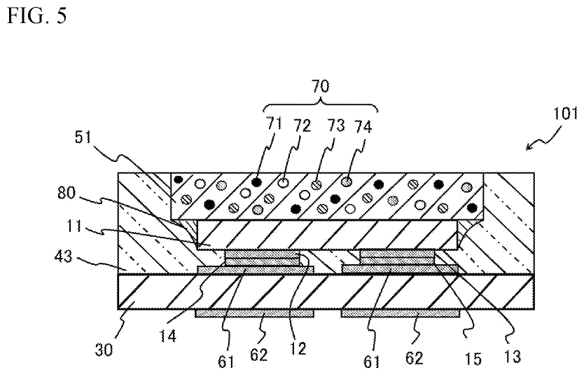

FIG. 5 is a schematic cross-sectional view illustrating a fifth example of a light-emitting device. The light-emitting device 101 may include, as the phosphor 70 included in the wavelength conversion member 51, the fourth phosphor 74 that absorbs and wavelength-converts at least a portion of the light from the light-emitting element 11 and has a light emission peak wavelength within a range from 400 nm to less than 700 nm.

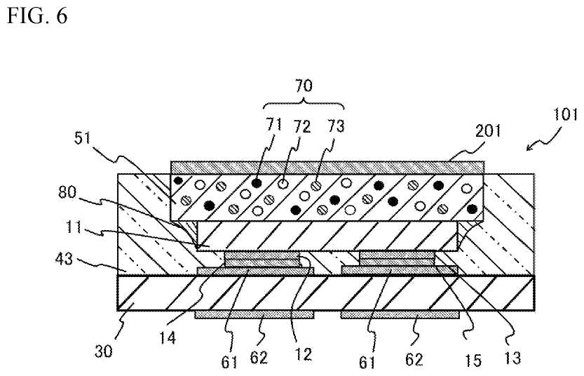

FIG. 6 is a schematic cross-sectional view illustrating a sixth example of a light-emitting device. The light-emitting device 101 may include a cut filter 201 having an average transmittance of 5% or less for light in a wavelength range from 400 nm to 780 nm on a light emission side of the wavelength conversion member 51. It is preferable that the cut filter 201 is movably disposed such that it can be disposed so as to block the light emission side of the wavelength conversion member 51 or can be disposed so as not to block the light emission side.

The wavelength conversion members illustrated in FIGS. 4 to 6 can be obtained by forming a resin composition for the wavelength conversion member including a phosphor and a resin that is a light-transmissive material in a liquid form into a sheet form by a method such as applying, printing, spraying, compression molding, transfer molding, injection molding, or potting. Examples of the resin that can be used for the wavelength conversion member include thermosetting resins, such as silicone resin, silicone-modified resin, epoxy resin, and phenol resin; and thermoplastic resins, such as polycarbonate resin, acrylic resin, methylpentene resin, and polynorbornene resin. As the resin used for the light guide members, a resin similar to the resin used for the wavelength conversion member can be used. For the wavelength conversion member and the light guide members, the same resin or different resins may be used.

Examples of the support include a support containing a ceramic, such as aluminum oxide, aluminum nitride, or silicon nitride, and a support containing a resin such as a fiber-reinforced resin. Examples of the resin contained in the support include thermosetting resins, such as epoxy resin, silicone resin, bismaleimide triazine (BT) resin, polyimide resin, and unsaturated polyester resin; and thermoplastic resins, such as polyphthalamide resin and nylon resin.

In order to absorb at least a portion of the light from the light-emitting element and emit light within the wavelength range of near-infrared light from the light-emitting device, the first phosphor and the second phosphor each preferably include at least one type of phosphor selected from the group consisting of a first oxide phosphor having a composition represented by the following formula (1), a second oxide phosphor having a composition represented by the following formula (2), a third oxide phosphor having a composition represented by the following formula (3), a fourth oxide phosphor having a composition represented by the following formula (4), a fifth oxide phosphor having a composition represented by the following formula (5), a sixth oxide phosphor having a composition represented by the following formula (6), a seventh oxide phosphor having a composition represented by the following formula (7), an eighth oxide phosphor having a composition represented by the following formula (8), and a ninth oxide phosphor having a composition represented by the following formula (9). Even when the first phosphor and the second phosphor have compositions represented by the same formula, they are differentiated by differences in, for example, the molar ratio of elements contained in the compositions: the first phosphor absorbs at least a portion of the light from the light-emitting element and emits light having a light emission peak wavelength in a first range from 700 nm to less than 800 nm, and the second phosphor absorbs at least a portion of the light from the light-emitting element and emits light having a light emission peak wavelength within a second range from 800 nm to less than 1100 nm.

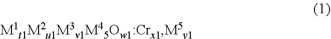

(In the formula (1): M¹ is at least one element selected from the group consisting of Li, Na, K, Rb, and Cs; M² is at least one element selected from the group consisting of Mg, Ca, Sr, Ba, and Zn; M³ is at least one element selected from the group consisting of B, Al, Ga, In, and rare earth elements; M⁴ is at least one element selected from the group consisting of Si, Ti, Ge, Zr, Sn, Hf, and Pb; M⁵ is at least one element selected from the group consisting of Eu, Ce, Tb, Pr, Nd, Sm, Yb, Ho, Er, Tm, Ni, and Mn; and t1, u1, v1, w1, x1, and y1 satisfy 0.7≤ t1≤ 1.3, 1.5≤ u1≤2.5, 0.7≤ v1≤1.3, 12.9≤w1≤15.1, 0<x1≤ 0.2, 0≤ y1≤0.10, and y1<x1.)

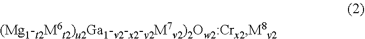

(In the formula (2), M⁶ is at least one element selected from the group consisting of Ca, Sr, Ba, Ni, and Zn; M⁷ is at least one element selected from the group consisting of B, Al, In, and Sc; M⁸ is at least one element selected from the group consisting of Eu, Ce, Tb, Pr, Nd, Sm, Yb, Ho, Er, Tm, and Mn; and t2, u2, v2, w2, x2, and y2 satisfy 0≤ t2≤ 0.8, 0.7≤ u2≤ 1.3, 0≤ v2≤0.8, 3.7≤ w2≤4.3, 0.02<x2≤0.3, 0≤y2≤0.2, and y2<×2.)

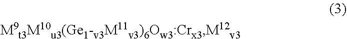

(In the formula (3): M⁹ is at least one element selected from the group consisting of Li, Na, K, Rb, and Cs; M¹⁰ is at least one element selected from the group consisting of Ca, Sr, Mg, Ba, and Zn; M¹¹ is at least one element selected from the group consisting of Si, Ti, Zr, Sn, Hf, and Pb; M¹² is at least one element selected from the group consisting of Eu, Ce, Tb, Pr, Nd, Sm, Yb, Ho, Er, Tm, Ni, and Mn; and t3, u3, v3, w3, x3, and y3 satisfy 1.5≤t3≤2.5, 0.7≤u3≤1.3, 0≤v3≤0.4, 12.9≤w3≤15.1, 0<x3≤0.2, 0≤y3≤ 0.10, and y3<x3.)

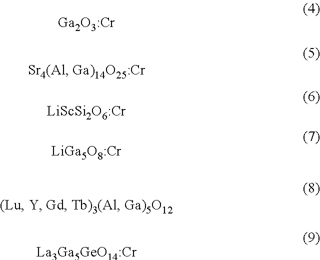

In order to absorb at least a portion of the light from the light-emitting element and emit light within the wavelength range of near-infrared light from the light-emitting device, the third phosphor preferably includes at least one type of phosphor selected from the group consisting of a tenth oxide phosphor having a composition represented by the following formula (10), an eleventh oxide phosphor having a composition represented by the following formula (11), and a twelfth oxide phosphor having a composition represented by the following formula (12).

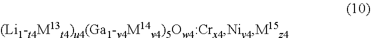

(In the formula (10): M¹³ is at least one element selected from the group consisting of Na, K, Rb, and Cs; M¹⁴ is at least one element selected from the group consisting of B, Al, Sc, In, and rare earth elements; M¹⁵ is at least one element selected from the group consisting of Si, Ge, Sn, Ti, Zr, Hf, Bi, V, Nb, and Ta; and t4, u4, v4, w4, x4, y4, and z4 satisfy 0≤ t4≤1.0, 0.7≤u4≤1.6, 0≤ v4<1.0, 7.85≤w4≤11.5, 0.05≤×4≤1.2, 0≤ y4≤0.5, 0.25<x4+y4≤ 1.2, y4<x4, and 0≤ z4≤ 0.5.)

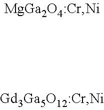

The light-emitting device preferably includes the fourth phosphor that absorbs at least a portion of the light from the light-emitting element and has a light emission peak wavelength within the fourth range from 400 nm to less than 700 nm. By including the fourth phosphor, the light-emitting device can not only emit light in the wavelength range of near-infrared light, but also emit light in the wavelength range of visible light from the fourth phosphor together with the light-emitting element.

In order to absorb at least a portion of the light from the light-emitting element and emit light in the wavelength range of visible light, the fourth phosphor preferably includes at least one type of phosphor selected from the group consisting of a phosphate phosphor having a composition represented by the following formula (13), a silicate phosphor having a composition represented by the following formula (14), a first aluminate phosphor having a composition represented by the following formula (15), a second aluminate phosphor having a composition represented by the following formula (16), a first nitride phosphor having a composition represented by the following formula (17), a second nitride phosphor having a composition represented by the following formula (18), a first fluoride phosphor having a composition represented by the following formula (19), and a second fluoride phosphor having a composition represented by the following formula (20).

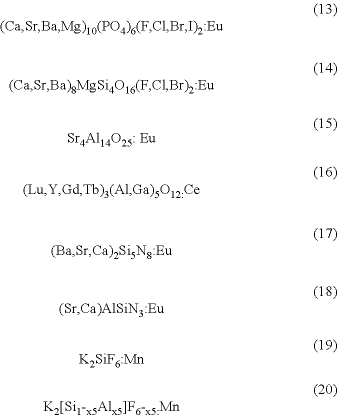

(In the formula (20), x5 satisfies 0<x5≤0.1.)

The light-emitting element preferably emits light having a light emission peak wavelength within a range from 250 nm to less than 700 nm. In particular, when the light-emitting element emits light having a light emission peak wavelength within a range from 380 nm to less than 700 nm, the light-emitting element can emit light in the wavelength range of visible light as well as light in the wavelength range of near-infrared light, and visibility of an object to be irradiated can be improved in the case in which the surroundings are dark or the case in which confidentiality, such as acquisition of image data without being noticed by the object to be irradiated, is unnecessary. The light-emitting element more preferably emits light having a light emission peak wavelength within a range from 380 nm to 500 nm, and still more preferably emits light having a light emission peak wavelength within a range from 380 nm to 450 nm.

A semiconductor light-emitting element is preferably used as the light-emitting element. By using a semiconductor light-emitting element as the light-emitting element, a light-emitting device provided with a stable light source that exhibits high efficiency, high output linearity with respect to an input, and strong resistance against mechanical impact can be provided. The semiconductor light-emitting element is preferably a nitride-based semiconductor light-emitting element, and more preferably a GaN-based semiconductor light-emitting element. As a nitride-based semiconductor light-emitting element, a GaN-based semiconductor light-emitting element having a composition represented by In_{X}Al_{Y}Ga_{1-X-Y}N (0≤X, 0≤Y, X+Y<1) can be used. The full width at half maximum of the emission spectrum of the light-emitting element can be, for example, 30 nm or less.

The light-emitting device preferably includes a cut filter having an average transmittance of 5% or less for light in a wavelength range from 400 nm to 780 nm on the light emission side. The average transmittance for light in the wavelength range from 400 nm to 780 nm of the cut filter may be 4% or less, 3% or less, 0% or more, 0.5% or more, or 1% or more. The cut filter may be manufactured using, for example, a composition containing a dye that absorbs light in a wavelength range from 400 nm to 780 nm. In addition, it is preferable that the cut filter is movably disposed such that it can be disposed so as to block the light emission side of the light-emitting device or can be disposed so as not to block the light emission side. In the light-emitting device including the cut filter, generation of light in a wavelength range of visible light from 400 nm to 780 nm can be reduced, and image data can be obtained without causing an object to be irradiated (such as a human or an animal) to feel glare and without being noticed by the object to be irradiated. The transmittance of the cut filter can be measured by, for example, vertically introducing a plurality of lights having mutually different light emission peak wavelengths within a range from 400 nm to 780 nm into the cut filter, measuring the emission intensities of the incident lights and the emitted lights using a spectrophotometer (for example, manufactured by Hitachi High-Tech Science Corporation), and comparing the measured emission intensities of the incident lights and the emitted lights. The transmittances of at least five lights having different light emission peak wavelengths within a range from 400 nm to 780 nm are measured in the same manner as that in the measurement of the transmittance described above, and the arithmetic mean value of the five points can be taken as the average transmittance within a range from 400 nm to 780 nm of the cut filter.

In the phosphor included in the wavelength conversion member, when the light-transmissive material contained in the wavelength conversion member is a resin, the total amount of the at least two types of phosphors each having a light emission peak wavelength in a different range, which are selected from the group consisting of the first phosphor, the second phosphor, and the third phosphor, is preferably within a range from 10 parts by mass to 300 parts by mass, more preferably within a range from 15 parts by mass to 250 parts by mass, and still more preferably within a range from 20 parts by mass to 200 parts by mass, with respect to 100 parts by mass of the resin. When the total amount of the phosphors included in the wavelength conversion member is within a range from 10 parts by mass to 300 parts by mass with respect to 100 parts by mass of the resin, an object to be irradiated can be irradiated with light having a high emission intensity within the wavelength range of near-infrared light, and the intensity of light reflected by the object to be irradiated also increases. Therefore, information on the reflectances of the object to be irradiated for lights having various near-infrared wavelengths can be easily obtained. As will be described below, by analyzing differences between the obtained reflectances for wavelengths of light, data on reflectances including the reflectance for the reflected light from the object to be irradiated can be converted into a colored image.

In order to irradiate the object to be irradiated with light within the wavelength range of near-infrared light from the light-emitting device, when the light-transmissive material contained in the wavelength conversion member is a resin, the amount of the first phosphor included in the wavelength conversion member is preferably within a range from 5 parts by mass to 100 parts by mass, and may be within a range from 10 parts by mass to 80 parts by mass, with respect to 100 parts by mass of the resin. When the first phosphor includes a plurality of types of first phosphors having different compositions, the amount of the first phosphors included in the wavelength conversion member means the total amount of the plurality of types of first phosphors.

In order to irradiate the object to be irradiated with light within the wavelength range of near-infrared light from the light-emitting device, when the light-transmissive material contained in the wavelength conversion member is a resin, the amount of the second phosphor included in the wavelength conversion member is preferably within a range from 10 parts by mass to 100 parts by mass, may be within a range from 15 parts by mass to 95 parts by mass, and may be within a range from 20 parts by mass to 90 parts by mass, with respect to 100 parts by mass of the resin. When the second phosphor includes a plurality of types of second phosphors having different compositions, the amount of the second phosphors included in the wavelength conversion member means the total amount of the plurality of types of second phosphors.

In order to irradiate the object to be irradiated with light within the wavelength range of near-infrared light from the light-emitting device, when the light-transmissive material contained in the wavelength conversion member is a resin, the amount of the third phosphor included in the wavelength conversion member is preferably within a range from 15 parts by mass to 100 parts by mass, may be within a range from 20 parts by mass to 95 parts by mass, and may be within a range from 25 parts by mass to 90 parts by mass with respect to 100 parts by mass of the resin. When the third phosphor includes a plurality of types of third phosphors having different compositions, the amount of the third phosphors included in the wavelength conversion member means the total amount of the plurality of types of third phosphors.

In a case in which the wavelength conversion member includes the fourth phosphor and the light-transmissive material contained in the wavelength conversion member is a resin, the total amount of the phosphor is preferably within a range from 10 parts by mass to 550 parts by mass, more preferably within a range from 20 parts by mass to 500 parts by mass, and more preferably within a range from 30 parts by mass to 450 parts by mass with respect to 100 parts by mass of the resin. In the case in which the wavelength conversion member includes the fourth phosphor, when the total amount of the phosphor is within a range from 10 parts by mass to 550 parts by mass with respect to 100 parts by mass of the resin, the object to be irradiated can be irradiated with light in the wavelength range of visible light as well as light within the wavelength range of near-infrared light.

In a case in which the wavelength conversion member includes the fourth phosphor and the light-transmissive material contained in the wavelength conversion member is a resin, the amount of the fourth phosphor is preferably within a range from 10 parts by mass to 200 parts by mass, more preferably within a range from 20 parts by mass to 180 parts by mass, and more preferably within a range from 30 parts by mass to 150 parts by mass with respect to 100 parts by mass of the resin. When the amount of the fourth phosphor included in the wavelength conversion member is within a range from 10 parts by mass to 200 parts by mass with respect to 100 parts by mass of the resin, the object to be irradiated can be irradiated with light in the wavelength range of visible light as well as light within the wavelength range of near-infrared light. When the fourth phosphor includes a plurality of types of fourth phosphors having different compositions, the amount of the fourth phosphors included in the wavelength conversion member means the total amount of the plurality of types of fourth phosphors.

In a case in which the wavelength conversion member contains the fourth phosphor, in the mass ratio of the amount of the fourth phosphor to the total amount of the at least two types of phosphors selected from the group consisting of the first phosphor, the second phosphor, and the third phosphor (the total amount of the at least two types of phosphors selected from the group consisting of the first phosphor, the second phosphor, and the third phosphor: the amount of the fourth phosphor), the amount of the fourth phosphor is preferably within a range from 10 parts by mass to 180 parts by mass, more preferably within a range from 20 parts by mass to 150 parts by mass, and still more preferably within a range from 30 parts by mass to 140 parts by mass with respect to 100 parts by mass of the total amount of the at least two types of phosphors selected from the group consisting of the first phosphor, the second phosphor, and the third phosphor. When the amount of the fourth phosphor is within a range from 10 parts by mass to 180 parts by mass with respect to 100 parts by mass of the total amount of the at least two types of phosphors selected from the group consisting of the first phosphor, the second phosphor, and the third phosphor, the light-emitting device can irradiate the object to be irradiated with light in the wavelength range of visible light as well as light within the wavelength range of near-infrared light having a high emission intensity to an extent that allows coloring due to differences in reflectance to be described below.

In an emission spectrum of the light-emitting device, when the maximum value of an emission intensity in a range from 700 nm or more is 100%, the minimum value of an emission intensity within a range from 700 nm to 1400 nm is preferably 5% or more. In the emission spectrum of the light-emitting device, when the maximum value of the emission intensity in a range from 700 nm or more is 100% and the minimum value of the emission intensity within a range from 700 nm to 1400 nm is 5% or more, the intensity of near-infrared light reflected by the object to be irradiated also increases, and information on the reflectances of the object to be irradiated for lights having various near-infrared wavelengths can be easily obtained. Therefore, by analyzing the differences between reflectances for wavelengths of light in more detail, data as a clearer color image can be obtained.

In the emission spectrum of the light-emitting device, when the maximum value of an emission intensity in a range from 700 nm or more is 100%, the minimum value of an emission intensity within a range from 800 nm to 1200 nm is preferably 10% or more. In the emission spectrum of the light-emitting device, when the maximum value of the emission intensity in a range from 700 nm or more is 100% and the minimum value of the emission intensity within a range from 800 nm to 1200 nm is 10% or more, the intensity of near-infrared light reflected by the object to be irradiated also increases more, and information on the reflectances of the object to be irradiated for lights having various near-infrared wavelengths can be more easily obtained. Therefore, by analyzing differences between reflectances for wavelengths of light in more detail, data as a clearer color image can be obtained.

The illumination device preferably includes a light-emitting device and at least one type of auxiliary light source selected from the group consisting of a tungsten lamp, a xenon lamp, and a halogen lamp. By the illumination device including the light-emitting device and at least one type of auxiliary light source selected from the group consisting of a tungsten lamp, a xenon lamp, and a halogen lamp, light in a wavelength range that is insufficient in near-infrared light from the light-emitting device can be supplemented, and the object to be irradiated can be irradiated with light in the wavelength range of near-infrared light. Further, by analyzing the differences between reflectances for lights in the wavelength range of near-infrared light from the object to be irradiated, data as a clear color image can be obtained.

The night-vision device includes a light-emitting device or an illumination device, an infrared camera, and an image processing unit that analyzes an image captured by the infrared camera and reproduces colors in a visible light region. The night-vision device preferably includes a display unit that displays the image in the visible light region reproduced by the image processing unit.

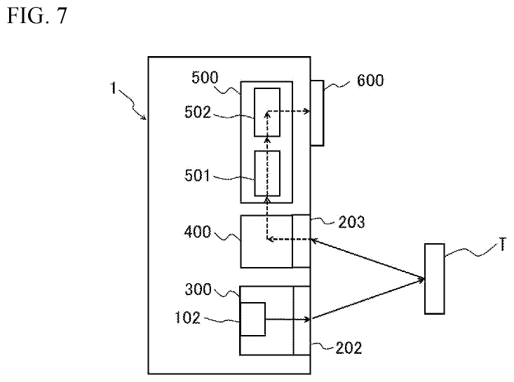

FIG. 7 is a diagram schematically illustrating a schematic configuration of an example of a night-vision device including a light-emitting device. A night-vision device 1 includes an illumination device 300 including a light-emitting device 102 serving as a light source, an infrared camera 400 as an infrared detector, and an image processing unit 500 that analyzes signals, which are image data received by the infrared camera, and reproduces colors in the visible light region. The night-vision device 1 includes a display unit 600 that performs pseudo colorization on the signals processed by the image processing unit 500 and performs display. The night-vision device 1 may include a movable first cut filter 202 in a portion of the illumination device 300 from which light is emitted, and may include a movable second cut filter 203 in a portion of the infrared camera 400 on which light is incident. An object to be irradiated Tis irradiated with the light emitted from the illumination device 300 in the night-vision device 1. The object to be irradiated T reflects the light emitted from the illumination device 300. The light reflected from the object to be irradiated T is received by the infrared camera 400 as an infrared detector. The infrared camera 400 may include an optical system, such as a reflection mirror or an objective lens. In the night-vision device 1, the image processing unit 500 analyzes signals of the reflected light from the object to be irradiated T received by the infrared camera 400. The night-vision device 1 may include an amplifier that amplifies the signals of the reflected light from the object to be irradiated T received by the infrared camera 400, and transmits the amplified signals to the image processing unit 500. The image processing unit 500 includes a signal processing device 501 that analyzes the signals, such as the wavelengths and intensities of the reflected light from the object to be irradiated T received by the infrared camera 400, and a color conversion unit 502 that generates pseudo colors with the respective signals regarded as, for example, red (R), blue (B), and green (G) according to the different wavelengths of the reflected light by the signal processing device 501. For example, when the wavelengths of the reflected light from the object to be irradiated T are 780 nm, 870 nm, and 940 nm, data in which the relationship between the corresponding wavelength and the corresponding color of the reflected light is set can be stored in a storage unit, such as a memory, in advance, and based on the stored data, the color conversion unit 502 can convert the respective wavelengths of the reflected light into colors such as red (R), blue (B), and green (G) to display a pseudo-colored image as a color image on the display unit 600, such as a liquid crystal display. In the reflected light from the object to be irradiated T received by the infrared camera 400, the differences between reflectances for wavelengths or the like are detected by the image processing unit 500, clearer pseudo colors are generated by the color conversion unit 502, and a color image is displayed on the display unit 600, such as a liquid crystal display. In FIG. 7, the arrows indicate light or signals by the light.

Note that, image data obtained by irradiation with near-infrared light often becomes an unclear image because the amount of infrared radiation energy is determined using a heat detection sensor, such as an infrared thermography, to detect differences in thermal temperature of the object to be irradiated, and the differences are represented as a black-and-white image.

The night-vision device according to the present disclosure can irradiate the object to be irradiated with near-infrared light having a high light emission intensity from the light-emitting device, receive reflected light from the object to be irradiated as image data with the infrared camera, analyze signals, which are the image data, and perform pseudo colorization by sorting the signals into red (R), blue (B), and green (G) according to the wavelengths of the reflected light. Thus, a clearer color image can be obtained.

Since the night-vision device includes, as a light source, the above-described light-emitting device including the light-emitting element and at least two types of phosphors selected from the group consisting of the first phosphor, the second phosphor, and the third phosphor, the object to be irradiated can be irradiated with near-infrared light having a high emission intensity, and by analyzing the reflected light from the object to be irradiated T, pseudo colorization can be performed according to the wavelengths of the reflected light or the like. Thus, a clearer color image can be displayed on the display unit. In addition, for example, the spectral properties of the second cut filter disposed in a portion that receives the reflected light from the object to be irradiated T may be supplemented by deep learning. The night-vision device supplemented by the deep learning can determine the wavelengths or intensities of the reflected light from the object to be irradiated T received by the infrared camera in more detail, improve the accuracy of the pseudo colors, and display a clearer color image on the display unit.

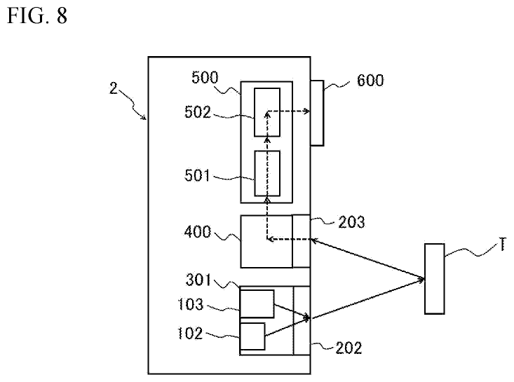

FIG. 8 is a schematic diagram illustrating a schematic configuration of an example of a night-vision device including the light-emitting device. A night-vision device 2 is different from the night-vision device 1 illustrated in FIG. 7 in that the night-vision device 2 includes the light-emitting device 102 serving as a light source, and an illumination device 301 including at least one auxiliary light source 103 selected from the group consisting of a tungsten lamp, a xenon lamp, and a halogen lamp. the rest of the schematic configuration is the same as that of the night-vision device 1 illustrated in FIG. 7. In FIG. 8, the arrows indicate light or signals by the light.

### EXAMPLES

The present invention will be described in detail hereinafter using examples. However, the present invention is not limited to these examples.

### Example 1

A light-emitting device of the embodiment illustrated in FIG. 1 including a molded body having a recessed portion, a light-emitting element disposed on a bottom surface of the recessed portion, and a wavelength conversion member disposed in the recessed portion and covering the light-emitting element was manufactured. As an excitation light source of the light-emitting device, a GaN-based semiconductor light-emitting element that emits light having a light emission peak wavelength of 440 nm was used. The light-emitting element was mounted on the bottom surface of the recessed portion via a conductive member. The wavelength conversion member includes a silicone resin as a light-transmissive material, and a first phosphor, a second phosphor, and a third phosphor each of which absorbs at least a portion of light emitted from the light-emitting element and emits light having a light emission peak wavelength in a different range. A resin composition for the wavelength conversion member was disposed in the recessed portion by potting. The resin composition for the wavelength conversion member was cured to manufacture the light-emitting device according to Example 1. Table 1 shows the types and light emission peak wavelengths of the first phosphor, the second phosphor, and the third phosphor included in the light-emitting device according to Example 1, and the amounts of the respective phosphors with respect to 100 parts by mass of the silicone resin in the resin composition for the wavelength conversion member. In the present specification, the symbol “-” in the tables indicates that there is no corresponding numerical value to the item.

### Example 2

A light-emitting device was manufactured in the same manner as that in Example 1 except that the types of the first phosphor, the second phosphor, and the third phosphor included in the light-emitting device and the amounts of the respective phosphors with respect to 100 parts by mass of the silicone resin were as shown in Table 1.

### Example 3

A light-emitting device of the embodiment illustrated in FIG. 3 was manufactured in the same manner as that in Example 1 except that the fourth phosphor was included, and the types of the first phosphor, the second phosphor, the third phosphor, and the fourth phosphor included in the light-emitting device and the amounts of the respective phosphors with respect to 100 parts by mass of the silicone resin were as shown in Table 2.

### Emission Spectrum

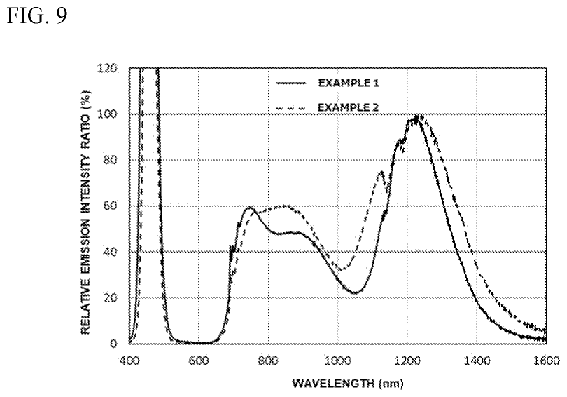

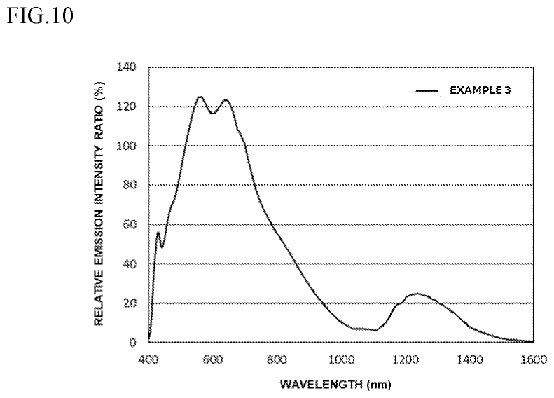

For the manufactured light-emitting devices, emission spectra indicating relative emission intensities (arbitrary values) with respect to wavelengths of the lights emitted from the respective light-emitting devices were measured using a total flux measuring device (manufactured by Nichia Corporation) using an integrating sphere in a state in which the lights were not blocked by a cut filter. FIG. 9 shows emission spectra of the light-emitting devices according to Example 1 and Example 2, and FIG. 10 shows an emission spectrum of the light-emitting device used as the light source of an illumination device according to Example 3. FIG. 10 shows the ratio (%) of the relative emission intensity when the highest emission intensity with respect to the wavelength of light was 100% in the emission spectrum of the light-emitting device.

TABLE 1

| | | | | Example 1 | Example 2 |
|---|---|---|---|---|---|
| | | | | Resin Composition | Resin Composition |
| | | | Light Emission | for Wavelength | for Wavelength |
| | | | Peak Wavelength | Conversion Member | Conversion Member |
| | | | (nm) | (parts by mass) | (parts by mass) |
| Silicone Resin | | | — | 100 | 100 |
| First Phosphor | Formula (4) | Ga₂O₃:Cr | 730 | 15 | 10 |
| Second Phosphor | Formula (2) | MgGa₂O₄:Cr | 880 | 50 | 30 |
| Third Phosphor | Formula (10) | LiGa₅O₈:Cr, Ni | 1230 | 40 | — |
| | Formula (10) | Li(Ga, AI)₅O₈:Cr, Ni | 1130 | — | 40 |
| | Formula (10) | Li(Ga, Sc)₅O₈:Cr, Ni | 1280 | — | 30 |

TABLE 2

| | | | | Example 3 |
|---|---|---|---|---|
| | | | | Resin Composition |
| | | | Light Emission | for Wavelength |
| | | | Peak Wavelength | Conversion Member |
| | | | (nm) | (parts by mass) |
| Silicone Resin | | | — | 100 |
| First Phosphor | Formula (4) | Ga₂O₃:Cr | 730 | 15 |
| Second Phosphor | Formula (3) | Na₂CaGe₆O₁₄:Cr | 827 | 35 |
| Third Phosphor | Formula (10) | LiGa₅O₈:Cr, Ni | 1230 | 40 |
| Fourth Phosphor | Formula (13) | Ca₁₀(PO₄)₆CI₂:Eu | 450 | 60 |
| | Formula (14) | Ca₈MgSi₄O₁₆CI₂:Eu | 520 | 3.7 |
| | Formula (16) | Lu₃AI₅O₁₂:Ce | 520 | 41.7 |
| | Formula (17) | (Ba, Sr)₂Si₅N₈:Eu | 600 | 5 |
| | Formula (18) | (Sr, Ca)AlSiN₃:Eu | 620 | 5 |

As shown in FIG. 9, in the emission spectra of the light-emitting devices according to Examples 1 and 2, when the maximum value of the emission intensity in a range from 700 nm or more was 100%, the minimum value of the emission intensity within a range from 700 nm to 1400 nm was 5% or more. In addition, in the emission spectra of the light-emitting devices according to Examples 1 and 2, when the maximum value of the emission intensity in a range from 700 nm or more was 100%, the minimum value of the emission intensity within a range from 800 nm to 1200 nm was 10% or more.

As shown in FIG. 10, in the emission spectrum of the light-emitting device according to Example 3, when the maximum value of the emission intensity in a range from 700 nm or more was 100%, the minimum value of the emission intensity within a range from 700 nm to 1400 nm was 5% or more. In addition, in the emission spectrum of the light-emitting device according to Example 3, when the maximum value of the emission intensity in a range from 700 nm or more was 100%, the minimum value of the emission intensity within a range from 800 nm to 1200 nm was 10% or more. In addition, it was confirmed that the light-emitting device according to Example 3 emits light having a high emission intensity even in the wavelength range of visible light.

The light-emitting devices according to Examples 1 to 3 emitted light in the wavelength range of near-infrared light with a high emission intensity without causing the object to be irradiated to feel glare even when the surroundings were dark and without allowing the object to be irradiated to easily notice the emission of light. When the light-emitting devices according to Examples 1 to 3 are used in an illumination device or a night-vision device, near-infrared light having a high emission intensity is emitted from the light-emitting devices, and the intensity of the near-infrared light reflected by an object to be irradiated increases. Therefore, by analyzing differences between reflectances for wavelengths of the light in more detail, data as a clearer color image can be obtained.

The light-emitting device according to the present disclosure can irradiate an object to be irradiated with near-infrared light even in the dark, and can be used as an illumination device or a night-vision device for security, an illumination device or a night-vision device that records or observes the ecology of nocturnal animals or the like, or a light-emitting device for vehicles, such as autonomous driving vehicles.

1. A light-emitting device comprising:
a light-emitting element; and
a phosphor that absorbs at least a portion of light from the light-emitting element and emits light, wherein
the phosphor includes two or more types of phosphors each having a light emission peak wavelength in a different range, the two or more types of phosphors being selected from the group consisting of a first phosphor having a light emission peak wavelength within a first range of 700 nm to less than 800 nm, a second phosphor having a light emission peak wavelength within a second range of 800 nm to less than 1100 nm, and a third phosphor having a light emission peak wavelength within a third range of 1100 nm to less than 1500 nm.

2. The light-emitting device according to claim 1, wherein the light-emitting element has a light emission peak wavelength within a range of 250 nm to less than 700 nm.

3. The light-emitting device according to claim 1, wherein in an emission spectrum of the light-emitting device, when a maximum value of an emission intensity in a range of 700 nm or more is 100%, a minimum value of an emission intensity within a range of 700 nm to 1400 nm is 5% or more.

4. The light-emitting device according to claim 1, wherein in an emission spectrum of the light-emitting device, when a maximum value of an emission intensity in a range of 700 nm or more is 100%, a minimum value of an emission intensity in a range of 800 nm to 1200 nm is 10% or more.

5. The light-emitting device according to claim 1, wherein the first phosphor and the second phosphor each include at least one type of phosphor selected from the group consisting of a first oxide phosphor having a composition represented by Formula (1), a second oxide phosphor having a composition represented by Formula (2), a third oxide phosphor having a composition represented by Formula (3), a fourth oxide phosphor having a composition represented by Formula (4), a fifth oxide phosphor having a composition represented by Formula (5), a sixth oxide phosphor having a composition represented by Formula (6), a seventh oxide phosphor having a composition represented by Formula (7), an eighth oxide phosphor having a composition represented by Formula (8), and a ninth oxide phosphor having a composition represented by Formula (9), 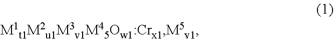
wherein in the formula (1), M¹ is at least one element selected from the group consisting of Li, Na, K, Rb, and Cs; M² is at least one element selected from the group consisting of Mg, Ca, Sr, Ba, and Zn; M³ is at least one element selected from the group consisting of B, Al, Ga, In, and rare earth elements; M⁴ is at least one element selected from the group consisting of Si, Ti, Ge, Zr, Sn, Hf, and Pb; M⁵ is at least one element selected from the group consisting of Eu, Ce, Tb, Pr, Nd, Sm, Yb, Ho, Er, Tm, Ni, and Mn; and t1, u1, v1, w1, x1, and y1 satisfy 0.7≤t1≤1.3, 1.5≤u1≤2.5, 0.7≤v1≤1.3, 12.9≤w1≤15.1, 0<x1≤0.2, 0≤y1≤0.10, and y1<x1; 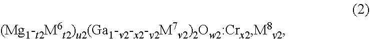
wherein in the formula (2), M⁶ is at least one element selected from the group consisting of Ca, Sr, Ba, Ni, and Zn; M⁷ is at least one element selected from the group consisting of B, Al, In, and Sc; M⁸ is at least one element selected from the group consisting of Eu, Ce, Tb, Pr, Nd, Sm, Yb, Ho, Er, Tm, and Mn; and t2, u2, v2, w2, x2, and y2 satisfy 0≤t2≤0.8, 0.7≤u2≤1.3, 0≤v2≤0.8, 3.7≤w2≤4.3, 0.02<x2≤0.3, 0≤y2≤0.2, and y2<x2; 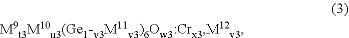
wherein in the formula (3), M⁹ is at least one element selected from the group consisting of Li, Na, K, Rb, and Cs; M¹⁰ is at least one element selected from the group consisting of Ca, Sr, Mg, Ba, and Zn; M¹¹ is at least one element selected from the group consisting of Si, Ti, Zr, Sn, Hf, and Pb; M¹² is at least one element selected from the group consisting of Eu, Ce, Tb, Pr, Nd, Sm, Yb, Ho, Er, Tm, Ni, and Mn; and t3, u3, v3, w3, x3, and y3 satisfy 1.5≤t3≤2.5, 0.7≤u3≤1.3, 0≤v3≤0.4, 12.9≤w3≤15.1, 0<x3≤0.2, 0≤y3≤0.10, and y3<x3;

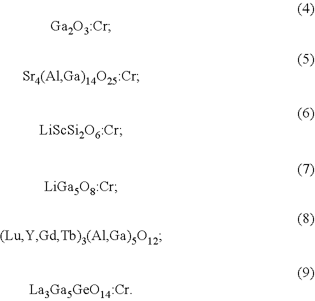

6. The light-emitting device according to claim 1, wherein the third phosphor includes at least one type of phosphor selected from the group consisting of a tenth oxide phosphor having a composition represented by Formula (10), an eleventh oxide phosphor having a composition represented by Formula (11), and a twelfth oxide phosphor having a composition represented by Formula (12), 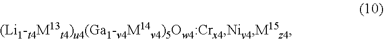
wherein in the formula (10), M¹³ is at least one element selected from the group consisting of Na, K, Rb, and Cs; M¹⁴ is at least one element selected from the group consisting of B, Al, Sc, In, and rare earth elements; M¹⁵ is at least one element selected from the group consisting of Si, Ge, Sn, Ti, Zr, Hf, Bi, V, Nb, and Ta; and t4, u4, v4, w4, x4, y4, and z4 satisfy 0≤t4≤1.0, 0.7≤u4≤ 1.6, 0≤ v4<1.0, 7.85≤ w4≤11.5, 0.05≤ x4≤1.2, 0≤y4≤0.5, 0.25<x4+y4≤1.2, y4<x4, and 0≤z4≤0.5;

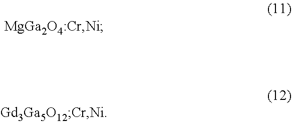

7. The light-emitting device according to claim 1, wherein the phosphor includes a fourth phosphor having a light emission peak wavelength within a fourth range of 400 nm to less than 700 nm.

8. The light-emitting device according to claim 7, wherein the fourth phosphor includes at least one type of phosphor selected from the group consisting of a phosphate phosphor having a composition represented by Formula (13), a silicate phosphor having a composition represented by Formula (14), a first aluminate phosphor having a composition represented by Formula (15), a second aluminate phosphor having a composition represented by Formula (16), a first nitride phosphor having a composition represented by Formula (17), a second nitride phosphor having a composition represented by Formula (18), a first fluoride phosphor having a composition represented by Formula (19), and a second fluoride phosphor having a composition represented by Formula (20), 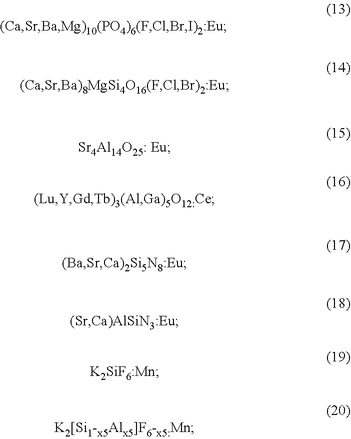
wherein in the formula (20), x5 satisfies 0<x5≤0.1.

9. The light-emitting device according to claim 1, further comprising a cut filter having an average transmittance that is 5% or less for light in a wavelength range of 400 nm to 780 nm.

10. An illumination device comprising:
the light-emitting device according to claim 1; and
at least one auxiliary light source selected from the group consisting of a tungsten lamp, a xenon lamp, and a halogen lamp.

11. A night-vision device comprising:
the light-emitting device according to claim 1;
an infrared camera; and
an image processing unit that analyzes an image captured by the infrared camera and reproduces a color in a visible light region.

12. The night-vision device according to claim 11, further comprising a display unit that displays the color in the visible light region reproduced by the image processing unit.

13. A night-vision device comprising:
the illumination device according to claim 10;
an infrared camera; and
an image processing unit that analyzes an image captured by the infrared camera and reproduces a color in a visible light region.

14. The night-vision device according to claim 13, further comprising a display unit that displays the color in the visible light region reproduced by the image processing unit.
